(19) United States
(12) Patent Application Publication
(10) Pub. No.: US 2020/0350124 A1
(43) Pub. Date: Nov. 5, 2020

(54) PASSIVE ON GLASS PLANARIZATION

(71) Applicant: QUALCOMM Incorporated, San Diego, CA (US)

(72) Inventors: Xia LI, San Diego, CA (US); Bin YANG, San Diego, CA (US); Kai LIU, San Diego, CA (US)

(21) Appl. No.: 16/748,775

(22) Filed: Jan. 21, 2020

Related U.S. Application Data
(60) Provisional application No. 62/843,014, filed on May 3, 2019.

(51) Int. Cl. H01G 4/30; H01L 49/02; H01G 4/33; H01G 4/012

(52) U.S. Cl. CPC H01G 4/306; H01L 28/60; H01G 4/008; H01G 4/012; H01G 4/33

(57) ABSTRACT

Planarization of the M1 metal layer reduces surface roughness and fills in pin-holes for a more reliable capacitor. For example, a MIM capacitor on a glass substrate may begin with patterning of the M1 layer, deposition of a planarization material, etch back the planarization material to planarize the M1 surface and fill in any pits/pin-holes. In addition, multiple-cycles of deposit and etch back further reduce M1 surface roughness and fill in possible pin-holes to acceptable level.

### CROSS-REFERENCE TO RELATED APPLICATIONS

The present Application for Patent claims the benefit of Provisional Application No. 62/843,014 entitled “PASSIVE ON GLASS PLANARIZATION” filed May 3, 2019, assigned to the assignee hereof, and expressly incorporated herein by reference in its entirety.

### FIELD OF DISCLOSURE

This disclosure relates generally to passive on glass substrates, and more specifically, but not exclusively, to planarized POG substrates.

### BACKGROUND

Radio-frequency (RF) filters may include an integrated passive device (IPD), such as a passive-on-glass (POG) device (e.g., a capacitor and/or an inductor). A conventional capacitor may be formed using a process that has 6 or more mask steps as part of an IPD fabrication process. Each mask used in the IPD fabrication process increases process cycle time, complexity, and cost to form an IPD. The fabrication process may add additional problems such as pits or holes and surface roughness.

For example, a typical capacitor includes two metal electrodes separated by an insulator, while a metal insulator metal (MIM) capacitor has a dielectric plate over it to reduce damage. When the first metal layer (M1) of the MIM capacitor is fabricated on a POG, the M1 layer ends up with a large surface roughness and pits. After annealing the M1 layer, the Cu grain size becomes bigger with higher temperature or longer annealing time. This results in no significant difference before/after annealing for pit size. In other words, annealing does not remove pits (pin-holes) completely. After annealing, pits of 0.2˜0.4 um still remain on the surface of the M1 layer.

POG M1 pits (pin-holes)˜0.2 um-0.4 um and surface large roughness 0.2˜1 um cause MIM capacitors Vbd failure and reliability degradation. The pin-hole is the first failure mechanism. The electrical field concentrates at pin-holes or pits tips that causes low MIM cap breakdown. RFFE (RF front-end) modules, for example, using POG have low-yield and reliability failures for manufacture due to the MIM Vbd failure. Run to run and batch to batch M1 pin-hole and surface pits roughness are not controllable by SATs' process. M1 surface pin-holes and pits roughness are the root causes of the MIM Vbd issue. It is induced by M1 plating (Cu) and the Cu planarization material (TiW, Cu) back etching process.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a method for manufacturing a passive device includes: applying a seed layer on a substrate; forming a first metal layer on the seed layer; depositing a planarization material on the first metal layer; etching back the planarization material; applying a dielectric on the planarization material; and forming a second metal layer on the dielectric.

In another aspect, a non-transitory computer-readable medium comprises instructions that when executed by a processor cause the processor to perform a method comprising: applying a seed layer on a substrate; forming a first metal layer on the seed layer; depositing a planarization material on the first metal layer; etching back the planarization material; applying a dielectric on the planarization material; and forming a second metal layer on the dielectric.

In still another aspect, a passive device includes: a substrate; a seed layer on the substrate; a first metal layer on the seed layer; a planarization material on the first metal layer; a dielectric on the planarization material; and a second metal layer on the dielectric.

In still another aspect, a passive device includes: a substrate; a seed layer on the substrate; first means for conducting on the seed layer; means for forming a barrier on the first means for conducting; means for insulating on the means for forming the barrier; and second means for conducting on the means for insulating.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary partial side view of a passive device in accordance with some examples of the disclosure;

FIG. 2 illustrates an exemplary partial side view of a passive device with a photo-resist film in accordance with some examples of the disclosure;

FIG. 3 illustrates an exemplary partial side view of a passive device with a second metal layer in accordance with some examples of the disclosure;

FIG. 4 illustrates an exemplary partial side view of a passive device with a polyimide layer in accordance with some examples of the disclosure;

FIG. 5 illustrates an exemplary partial side view of another passive device in accordance with some examples of the disclosure;

FIG. 6 illustrates an exemplary partial side view of another passive device with a photo-resist film in accordance with some examples of the disclosure;

FIG. 7 illustrates an exemplary partial side view of another passive device with a second metal layer in accordance with some examples of the disclosure;

FIG. 8 illustrates an exemplary partial side view of another passive device with a polyimide layer in accordance with some examples of the disclosure;

FIG. 9 illustrates an exemplary partial side view of still another passive device in accordance with some examples of the disclosure;

FIG. 10 illustrates an exemplary partial side view of still another passive device in accordance with some examples of the disclosure;

FIG. 11 illustrates an exemplary partial side view of still another passive device with a second metal layer in accordance with some examples of the disclosure;

FIG. 12 illustrates an exemplary partial side view of still another passive device with a polyimide layer in accordance with some examples of the disclosure;

FIG. 13 illustrates an exemplary partial side view of still another passive device in accordance with some examples of the disclosure;

FIG. 14 illustrates an exemplary partial side view of still another passive device in accordance with some examples of the disclosure;

FIG. 15 illustrates an exemplary partial side view of still another passive device with a second metal layer in accordance with some examples of the disclosure;

FIG. 16 illustrates an exemplary partial side view of still another passive device with a polyimide layer in accordance with some examples of the disclosure;

FIG. 17 illustrates a partial method for manufacturing a passive device in accordance with some examples of the disclosure;

FIG. 18 illustrates an exemplary mobile device in accordance with some examples of the disclosure; and

FIG. 19 illustrates various electronic devices that may be integrated with any of the aforementioned integrated device, semiconductor device, integrated circuit, die, interposer, package or package-on-package (PoP) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs.

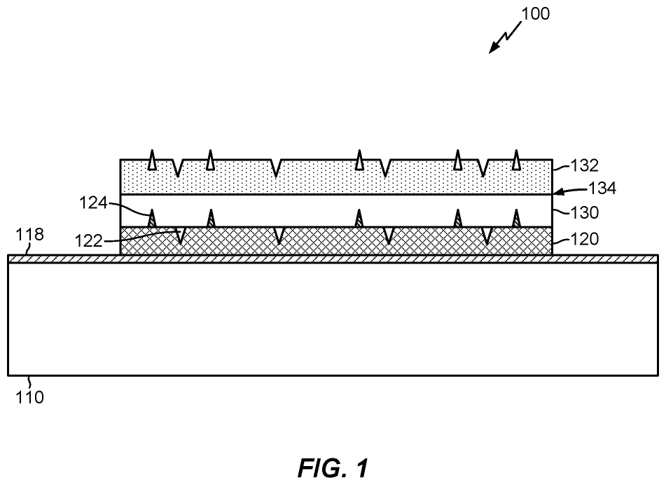

FIG. 1 illustrates an exemplary partial side view of a passive device in accordance with some examples of the disclosure. As shown in FIG. 1, a passive device 100 may include a substrate 110 (e.g., glass), a seed layer (e.g., copper) 118, and a first metal layer 120 applied or formed on the substrate 110. The first metal layer 120 may comprise Cu, Au, Ag, Al, or similar material and may be patterned as well as annealed for a certain length of time. The deposit, plating, or annealing may create pin holes 122 and pit tips 124 (surface ridges etc.). To reduce the negative impact of these features, the passive device 100 may include a planarization material 130 deposited on the patterned first metal layer 120. As can be seen, the planarization material 130 may include similar pin holes 122 and pit tips 124 in a sacrificial portion 132 as this layer may be a conformal layer that replicates the underlying imperfections. An etch back process (well known in the art) may be employed to remove the sacrificial portion 132 at an etch back level 134 to create a smooth surface, i.e., dry etch back process for surface planarization, etc. The planarization material 130 may comprise TiN, TiW, TaN, or TiWCu (or Oxide or SiN as discussed below) and may be created by depositing multiple layers (e.g. CVD or PVD deposition). The etch back process may planarize the first metal layer surface and fill in the holes and pits. It should be understood that the processes discussed herein related to the first metal layer may also be applied to other metal layers to reduce pin holes and surface roughness such as pit tips.

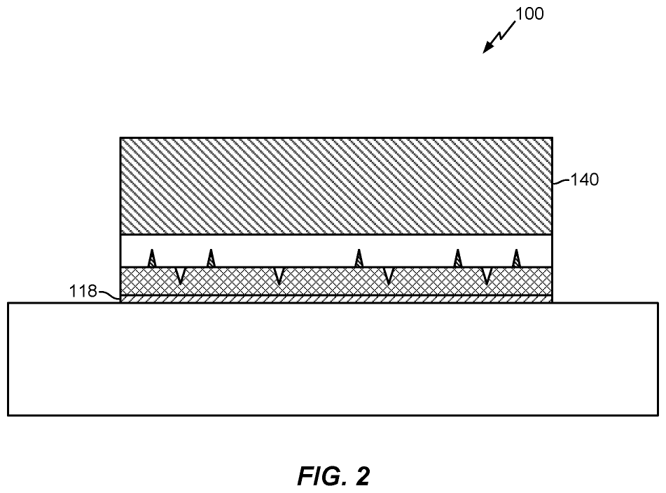

FIG. 2 illustrates an exemplary partial side view of a passive device with a photo-resist film in accordance with some examples of the disclosure. As shown in FIG. 2, the passive device 100 may include a photo-resist film 140 applied to the etched planarization material 130. The photo-resist film 140 protects the surface during normal processes associated with manufacturing a passive device such as etching of other areas not shown in the Figures (e.g., remove unwanted portion of the first metal layer or planarization material layer). These processes may include wet etching processes (such as to remove the TiN (planarization material layer), removal of portions of the seed layer 118 from other areas of the substrate and removal of portions of the first metal layer 120 that may affect the first metal layer 120 or the planarization material 130. The photo-resist film 140 may be developed and then removed after the processes in other areas are complete, i.e., lithographic focus on or off specific area for different kind tune photo resistance, etc.

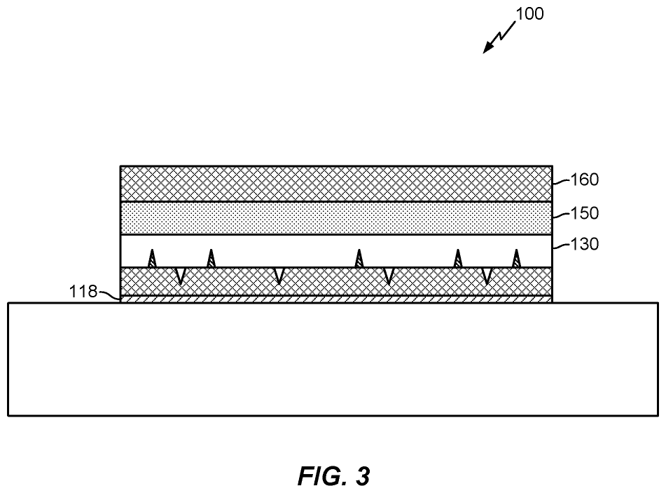

FIG. 3 illustrates an exemplary partial side view of a passive device with a second metal layer in accordance with some examples of the disclosure. As shown in FIG. 3, once the photo-resist film 140 is removed, a dielectric 150 may be applied on the planarization material 130 and a second metal layer 160 may be applied on the dielectric 150 and patterned. The second metal layer 160 may comprise Cu, Au, Ag, Al or similar material and the dielectric 150 may comprise SiN. The second metal layer 160, the dielectric 150, the planarization material 130, and the first metal layer 120 may comprise a capacitor, such as a MIM capacitor.

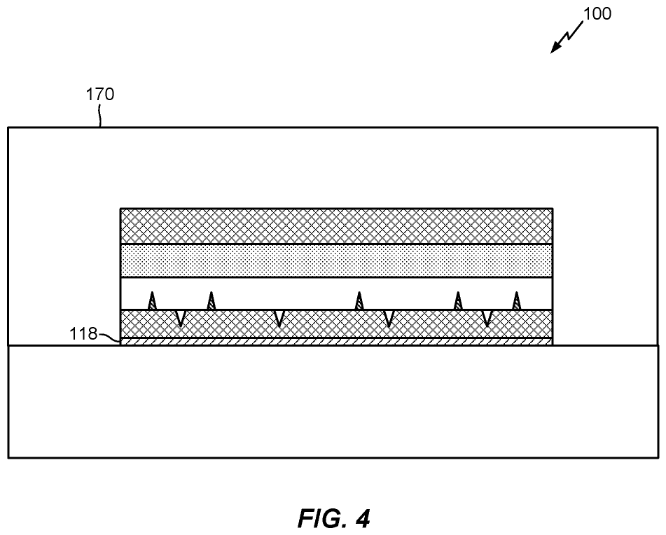

FIG. 4 illustrates an exemplary partial side view of a passive device with a polyimide layer in accordance with some examples of the disclosure. As shown in FIG. 4, the passive device 100 may be protected by encapsulating the capacitor in a mold compound 170, such as polyimide, as well as isolate the capacitor from other components include additional metal layers deposited on the mold compound 170.

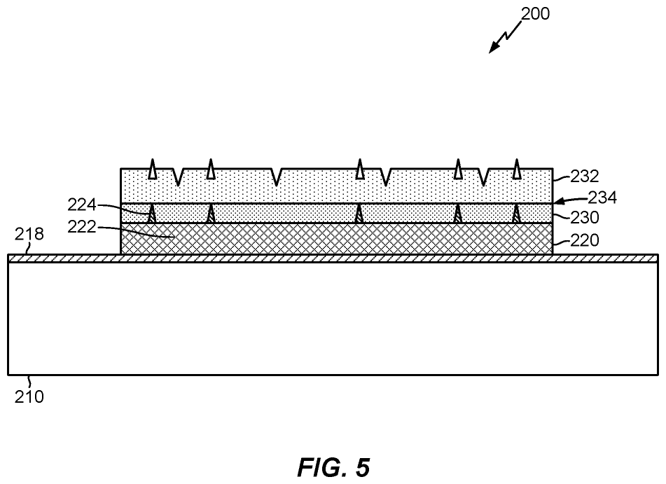

FIG. 5 illustrates an exemplary partial side view of another passive device in accordance with some examples of the disclosure. As shown in FIG. 5, a passive device 200 may include a substrate 210, a seed layer 218, and a first metal layer 220 applied on the seed layer 218. The first metal layer 220 may comprise Cu and may be patterned as well as annealed for a certain length of time. The annealing may create pin holes 222 and pit tips 224 (surface ridges etc.). To reduce the negative impact of these features, the passive device 200 may include a planarization material 230 deposited on the patterned first metal layer 220. As can be seen, the planarization material 230 may include similar pin holes 222 and pit tips 224 in a sacrificial portion 232 as this layer may be a conformal layer that replicates the underlying imperfections. An etch back process (well known in the art) may be employed to remove the sacrificial portion 232 at an etch back level 234 to create a smooth surface, i.e., dry etch back process for surface planarization, etc. The planarization material 230 may comprise Oxide or SiN and may be created by depositing multiple layers (e.g. CVD or PVD deposition). The etch back process may planarize the first metal layer surface and fill in the holes and pits. It should be understood that the processes discussed herein related to the first metal layer may also be applied to other metal layers to reduce pin holes and surface roughness such as pit tips.

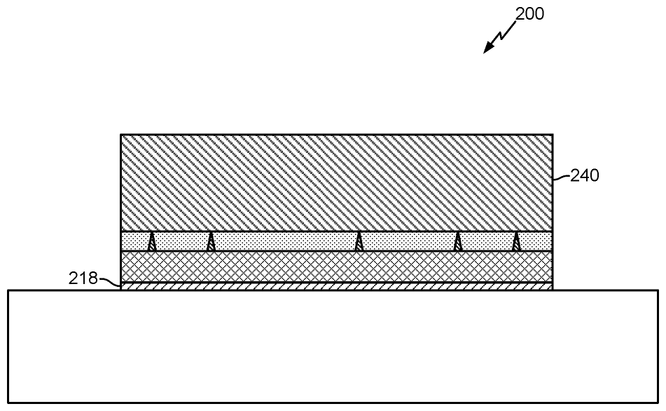

FIG. 6 illustrates an exemplary partial side view of another passive device with a photo-resist film in accordance with some examples of the disclosure. As shown in FIG. 6, the passive device 200 may include a photo-resist film 240 applied to the etched planarization material 230. The photo-resist film 240 protects the surface during normal processes associated with manufacturing a passive device such as etching of other areas not shown in the Figures. These processes may include wet etching processes (such as to remove the SiN or Oxide), removal of portions of the seed layer 118 from other areas of the substrate and removal of portions of the first metal layer 120 that may affect the first metal layer 120 or the planarization material 130. The photo-resist film 240 may be developed and then removed after the processes in other areas are complete, i.e., lithographic focus on or off specific area for different kind tune photo resistance, etc.

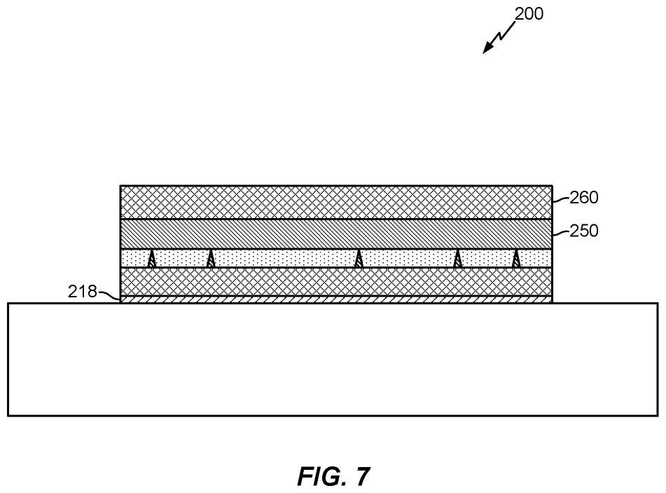

FIG. 7 illustrates an exemplary partial side view of another passive device with a second metal layer in accordance with some examples of the disclosure. As shown in FIG. 7, once the photo-resist film 240 is removed, a dielectric 250 may be applied on the planarization material 230 and a second metal layer 260 may be applied on the dielectric 250 and patterned. The second metal layer 260 may comprise Cu and the dielectric 250 may comprise SiN. The second metal layer 260, the dielectric 250, the planarization material 230, and the first metal layer 220 may comprise a capacitor, such as a MIM capacitor.

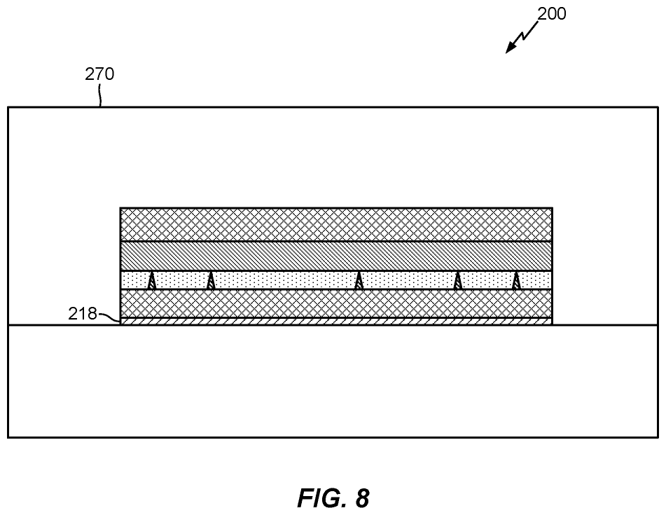

FIG. 8 illustrates an exemplary partial side view of another passive device with a polyimide layer in accordance with some examples of the disclosure. As shown in FIG. 8, the passive device 200 may be protected by encapsulating the capacitor in a mold compound 270, such as polyimide, as well as isolate the capacitor from other components include additional metal layers deposited on the mold compound 270.

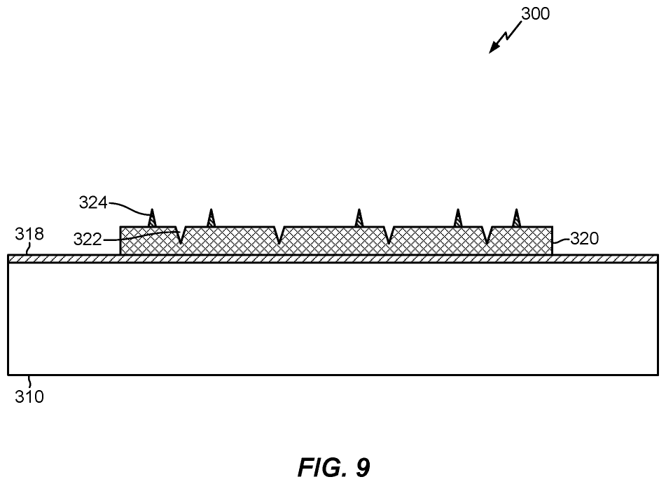

FIG. 9 illustrates an exemplary partial side view of still another passive device in accordance with some examples of the disclosure. As shown in FIG. 9, a passive device 300 may include a substrate 310, a seed layer 318, and a first metal layer 320 applied on the seed layer 318. The first metal layer 320 may comprise Cu and may be patterned as well as annealed for a certain length of time. The deposit, plating, or annealing may create pin holes 322 and pit tips 324 (surface ridges etc.). A temporary TiN layer (not shown) may be applied on the first metal layer 320 and etched back to remove the temporary layer. The Cu seed layer used to create the first metal layer 310 may be etched back from other areas of the substrate that are not desired at the same time the temporary layer is etched away.

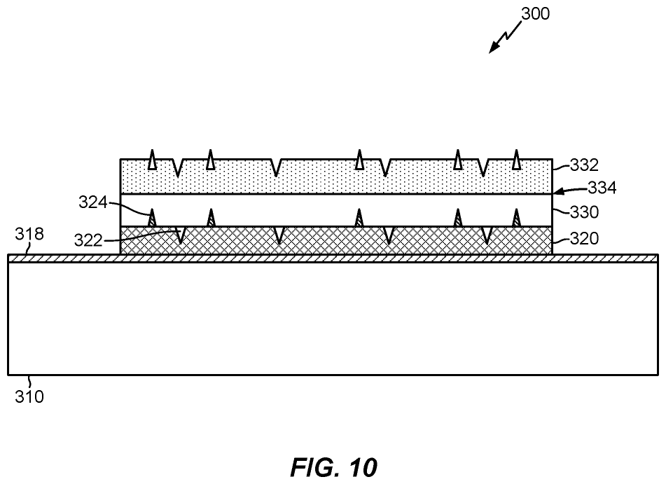

FIG. 10 illustrates an exemplary partial side view of still another passive device in accordance with some examples of the disclosure. As shown in FIG. 10, to reduce the negative impact of these features, the passive device 300 may include a planarization material 330 deposited on the patterned first metal layer 320. As can be seen, the planarization material 330 may include similar pin holes 322 and pit tips 324 in a sacrificial portion 332 as this layer may be a conformal layer that replicates the underlying imperfections. An etch back process (well known in the art) may be employed to remove the sacrificial portion 332 at an etch back level 334 to create a smooth surface, i.e., dry etch back process for surface planarization, etc. The planarization material 330 may comprise TiN, TiW, TaW, or TiWCu (or Oxide or SiN as discussed elsewhere) and may be created by depositing multiple layers (e.g. CVD or PVD deposition). The etch back process may planarize the first metal layer surface and fill in the holes and pits. Additional processes may include wet etching processes (such as to remove the TiN (planarization material layer), removal of portions of the seed layer 318 from other areas of the substrate and removal of portions of the first metal layer 320 that may affect the first metal layer 320 or the planarization material 330. It should be understood that the processes discussed herein related to the first metal layer may also be applied to other metal layers to reduce pin holes and surface roughness such as pit tips.

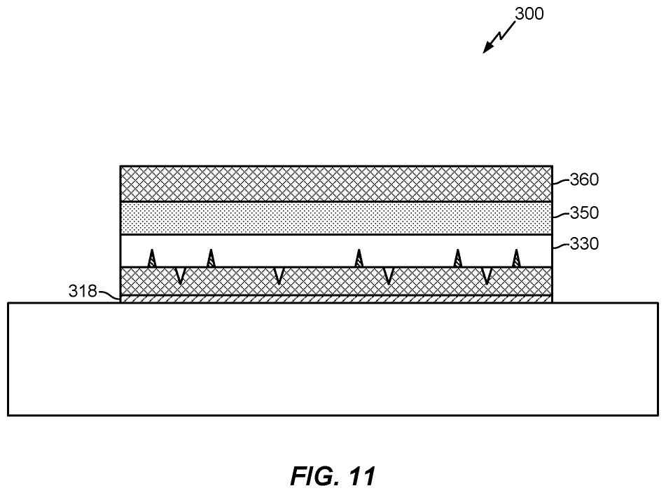

FIG. 11 illustrates an exemplary partial side view of a passive device with a second metal layer in accordance with some examples of the disclosure. As shown in FIG. 11, a dielectric 350 may be applied on the planarization material 330 and a second metal layer 360 may be applied on the dielectric 350 and patterned. The second metal layer 360 may comprise Cu and the dielectric 350 may comprise SiN. The second metal layer 360, the dielectric 350, the planarization material 330, and the first metal layer 320 may comprise a capacitor, such as a MIM capacitor.

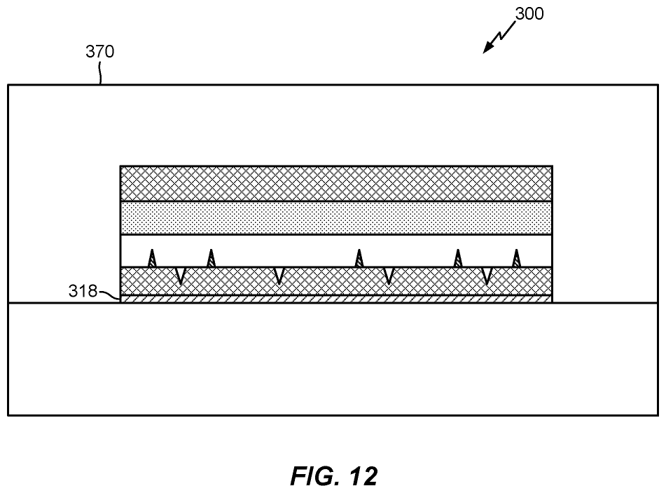

FIG. 12 illustrates an exemplary partial side view of a passive device with a polyimide layer in accordance with some examples of the disclosure. As shown in FIG. 12, the passive device 300 may be protected by encapsulating the capacitor in a mold compound 370, such as polyimide, as well as isolate the capacitor from other components include additional metal layers deposited on the mold compound 370.

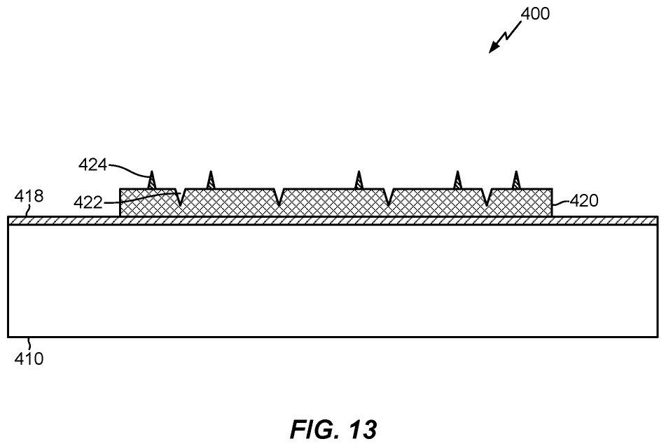

FIG. 13 illustrates an exemplary partial side view of another passive device in accordance with some examples of the disclosure. As shown in FIG. 13, a passive device 400 may include a substrate 410, a seed layer 418, and a first metal layer 420 applied on the seed layer 418. The first metal layer 420 may comprise Cu and may be patterned as well as annealed for a certain length of time. The deposit, plating, or annealing may create pin holes 422 and pit tips 424 (surface ridges etc.). A temporary TiN layer (not shown) may be applied on the first metal layer 320 and etched back to remove the temporary layer. The Cu seed layer used to create the first metal layer 310 may be etched back from other areas of the substrate that are not desired at the same time the temporary layer is etched away.

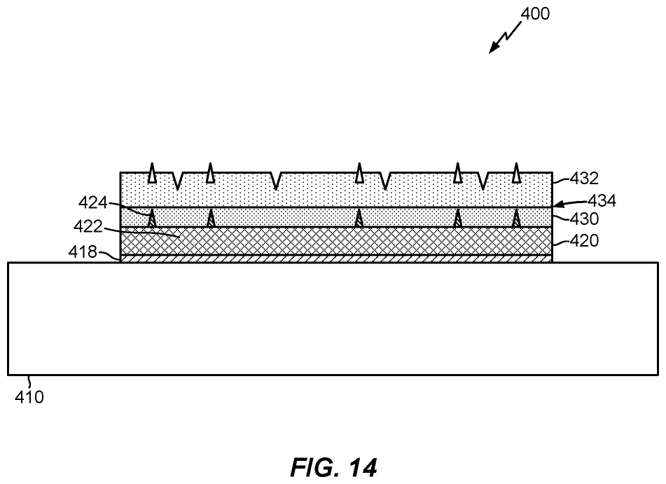

FIG. 14 illustrates an exemplary partial side view of another passive device with a photo-resist film in accordance with some examples of the disclosure. As shown in FIG. 14, to reduce the negative impact of these features, the passive device 400 may include a planarization material 430 deposited on the patterned first metal layer 420. As can be seen, the planarization material 430 may include similar pin holes 422 and pit tips 424 in a sacrificial portion 432 as this layer may be a conformal layer that replicates the underlying imperfections. An etch back process (well known in the art) may be employed to remove the sacrificial portion 432 at an etch back level 434 to create a smooth surface, i.e., dry etch back process for surface planarization, etc. The planarization material 430 may comprise Oxide or SiN and may be created by depositing multiple layers (e.g. CVD or PVD deposition). The etch back process may planarize the first metal layer surface and fill in the holes and pits. Additional processes may include wet etching processes (such as to remove the Oxide or SiN (planarization material layer), removal of portions of the seed layer 418 from other areas of the substrate and removal of portions of the first metal layer 420 that may affect the first metal layer 420 or the planarization material 430. It should be understood that the processes discussed herein related to the first metal layer may also be applied to other metal layers to reduce pin holes and surface roughness such as pit tips.

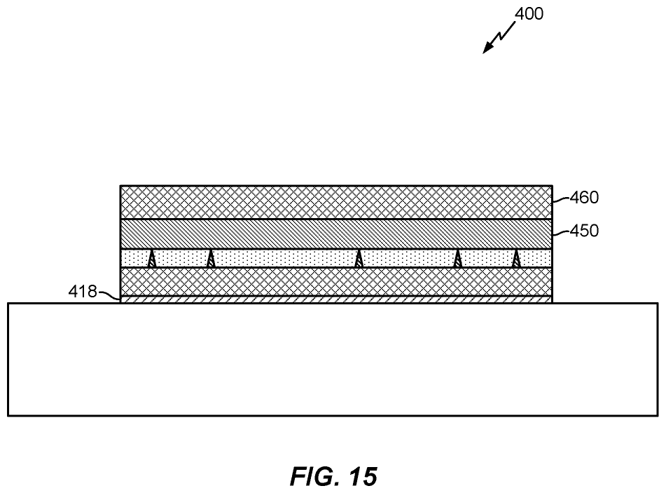

FIG. 15 illustrates an exemplary partial side view of another passive device with a second metal layer in accordance with some examples of the disclosure. As shown in FIG. 15, a dielectric 450 may be applied on the planarization material 430 and a second metal layer 460 may be applied on the dielectric 450 and patterned. The second metal layer 460 may comprise Cu and the dielectric 450 may comprise SiN. The second metal layer 460, the dielectric 450, the planarization material 430, and the first metal layer 420 may comprise a capacitor, such as a MIM capacitor. It should be understood that the thicker dielectric may allow a reduction in the capacitance density.

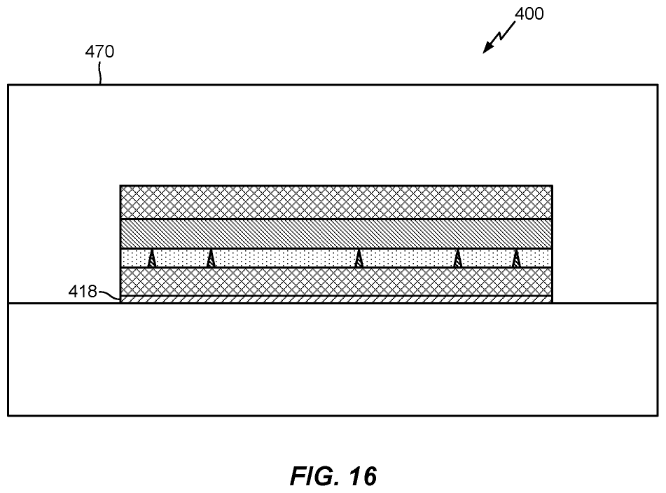

FIG. 16 illustrates an exemplary partial side view of another passive device with a polyimide layer in accordance with some examples of the disclosure. As shown in FIG. 16, the passive device 400 may be protected by encapsulating the capacitor in a mold compound 470, such as polyimide, as well as isolate the capacitor from other components include additional metal layers deposited on the mold compound 470.

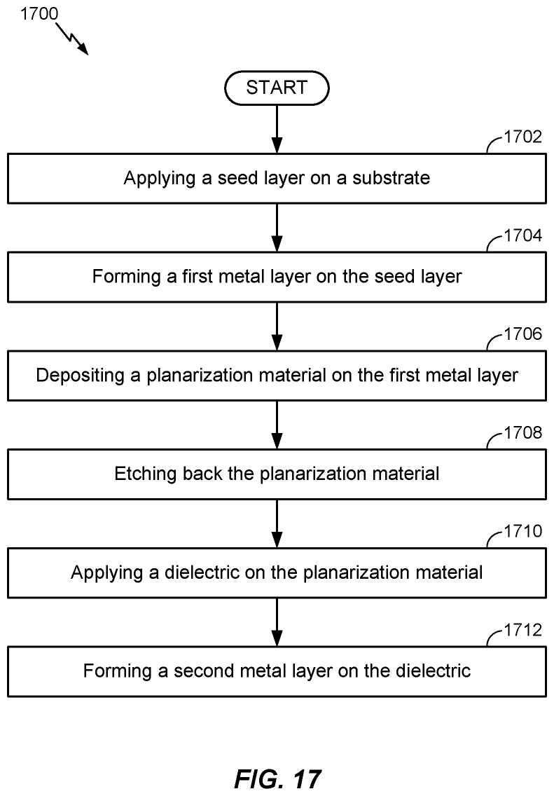

FIG. 17 illustrates a partial method for manufacturing a passive device in accordance with some examples of the disclosure. As shown in FIG. 17, the partial method 1700 may begin in block 1702 with applying a seed layer on a substrate. The partial method 1700 may continue in block 1704 with forming a first metal layer on the seed layer. The partial method 1700 may continue in block 1706 with depositing a planarization material on the first metal layer. The partial method 1700 may continue in block 1708 with etching back the planarization material for surface planarization. The partial method 1700 may continue in block 1710 with applying a dielectric on the planarization material. The partial method 1700 may conclude in block 1712 with forming a second metal layer on the dielectric. Additionally, the partial method 1700 may also include: applying a negative photo-resist film on the planarization material prior to applying the dielectric; exposing a portion of the negative photo-resist film; and removing an unexposed portion of the negative photo-resist film. Additionally, the partial method 1700 may include etching back the first metal layer and the planarization material after exposing the portion of the negative photo-resist film. Alternatively, the partial method 1700 may skip the negative photo-resist film process and include etching back the first metal layer and the planarization material before applying the dielectric.

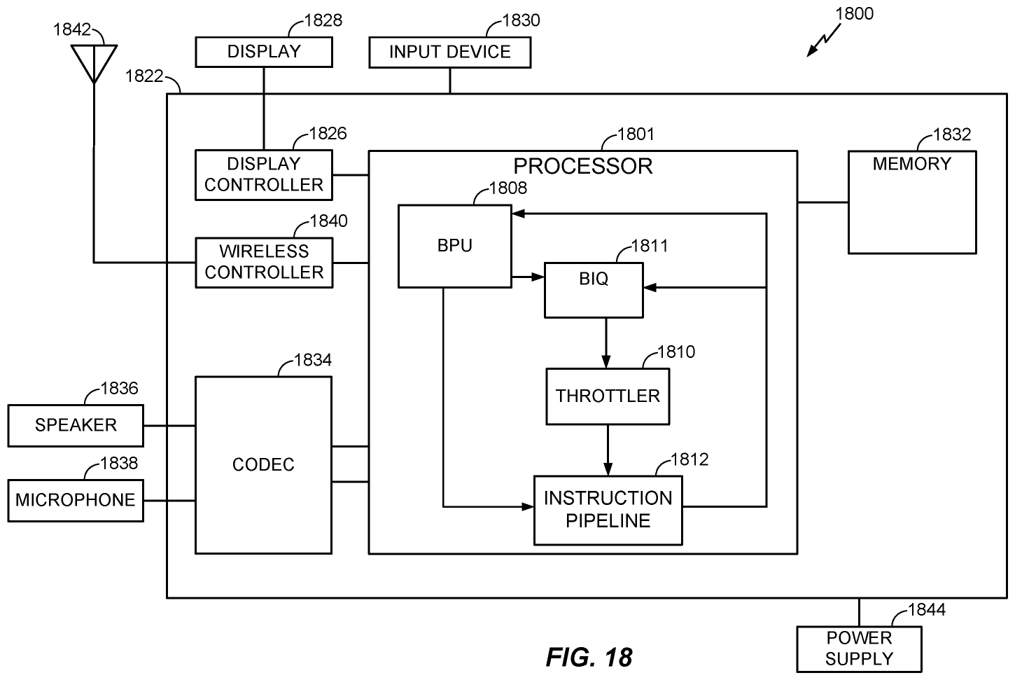

FIG. 18 illustrates an exemplary mobile device in accordance with some examples of the disclosure. Referring now to FIG. 18, a block diagram of a mobile device that is configured according to exemplary aspects is depicted and generally designated 1800. In some aspects, mobile device 1800 may be configured as a wireless communication device. As shown, mobile device 1800 includes processor 1801, which may be configured to implement the methods described herein in some aspects. Processor 1801 is shown to comprise instruction pipeline 1812, buffer processing unit (BPU) 1808, branch instruction queue (BIQ) 1811, and throttler 1810 as is well known in the art. Other well-known details (e.g., counters, entries, confidence fields, weighted sum, comparator, etc.) of these blocks have been omitted from this view of processor 1801 for the sake of clarity.

Processor 1801 may be communicatively coupled to memory 1832 over a link, which may be a die-to-die or chip-to-chip link. Mobile device 1800 also include display 1828 and display controller 1826, with display controller 1826 coupled to processor 1801 and to display 1828.

In some aspects, FIG. 18 may include coder/decoder (CODEC) 1834 (e.g., an audio and/or voice CODEC) coupled to processor 1801; speaker 1836 and microphone 1838 coupled to CODEC 1834; and wireless controller 1840 (which may include a modem) coupled to wireless antenna 1842 and to processor 1801.

In a particular aspect, where one or more of the above-mentioned blocks are present, processor 1801, display controller 1826, memory 1832, CODEC 1834, and wireless controller 1840 can be included in a system-in-package or system-on-chip device 1822. Input device 1830 (e.g., physical or virtual keyboard), power supply 1844 (e.g., battery), display 1828, input device 1830, speaker 1836, microphone 1838, wireless antenna 1842, and power supply 1844 may be external to system-on-chip device 1822 and may be coupled to a component of system-on-chip device 1822, such as an interface or a controller.

It should be noted that although FIG. 18 depicts a mobile device, processor 1801 and memory 1832 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

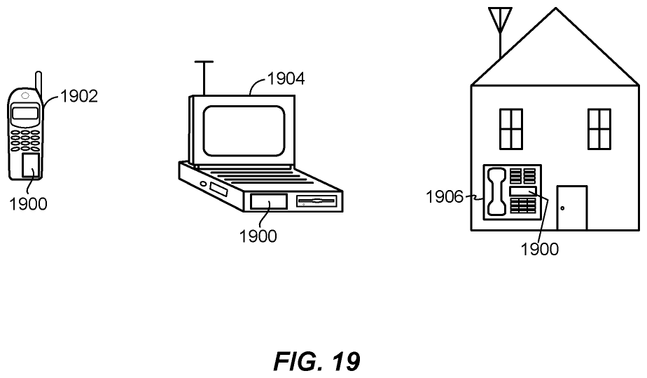

FIG. 19 illustrates various electronic devices that may be integrated with any of the aforementioned integrated device, semiconductor device, integrated circuit, die, interposer, package or package-on-package (PoP) in accordance with some examples of the disclosure. For example, a mobile phone device 1902, a laptop computer device 1904, and a fixed location terminal device 1906 may include an integrated device 1900 as described herein. The integrated device 1900 may be, for example, any of the integrated circuits, dies, integrated devices, integrated device packages, integrated circuit devices, device packages, integrated circuit (IC) packages, package-on-package devices described herein. The devices 1902, 1904, 1906 illustrated in FIG. 19 are merely exemplary. Other electronic devices may also feature the integrated device 1900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. For example, in one aspect, a passive device may comprise a substrate; a seed layer on the substrate; first means for conducting (e.g., a first metal layer) on the seed layer; means for forming (e.g., planarization material) a barrier on the first means for conducting; means for insulating (e.g., a dielectric) on the means for forming the barrier; and second means for conducting (e.g., a second metal layer) on the means for insulating. It will be appreciated that the aforementioned aspects are merely provided as examples and the various aspects claimed are not limited to the specific references and/or illustrations cited as examples.

One or more of the components, processes, features, and/or functions illustrated in FIGS. 1-19 may be rearranged and/or combined into a single component, process, feature or function or incorporated in several components, processes, or functions. Additional elements, components, processes, and/or functions may also be added without departing from the disclosure. It should also be noted that FIGS. 1-19 and its corresponding description in the present disclosure is not limited to dies and/or ICs. In some implementations, FIGS. 1-19 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions of this method.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A method for manufacturing a passive device, the method comprising:
applying a seed layer on a substrate;
forming a first metal layer on the seed layer;
depositing a planarization material on the first metal layer;
etching back the planarization material;
applying a dielectric on the planarization material; and
forming a second metal layer on the dielectric.

2. The method of claim 1, further comprising:
applying a negative photo-resist film on the planarization material prior to applying the dielectric;
exposing a portion of the negative photo-resist film; and
removing an unexposed portion of the negative photo-resist film.

3. The method of claim 2, further comprising etching back the first metal layer and the planarization material after exposing the portion of the negative photo-resist film.

4. The method of claim 1, wherein the substrate comprises glass.

5. The method of claim 1, wherein the planarization material comprises one of TiN, TiW, TaN, TiWCu, Oxide or SiN.

6. The method of claim 1, wherein the first metal layer comprises Cu, Au, Ag, Al, or similar material.

7. The method of claim 1, wherein the second metal layer comprises Cu, Au, Ag, Al, or similar material.

8. The method of claim 1, wherein the dielectric comprises SiN, AlO₃, or high k material.

9. The method of claim 1, wherein the passive device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

10. A non-transitory computer-readable medium comprising instructions that when executed by a processor cause the processor to perform a method comprising:
applying a seed layer on a substrate;
forming a first metal layer on the seed layer;
depositing a planarization material on the first metal layer;
etching back the planarization material;
applying a dielectric on the planarization material; and
forming a second metal layer on the dielectric.

11. The non-transitory computer-readable medium of claim 10, wherein the method further comprises:
applying a negative photo-resist film on the planarization material prior to applying the dielectric;
exposing a portion of the negative photo-resist film; and
removing an unexposed portion of the negative photo-resist film.

12. The non-transitory computer-readable medium of claim 11, wherein the method further comprises etching back the first metal layer and the planarization material after exposing the portion of the negative photo-resist film.

13. The non-transitory computer-readable medium of claim 10, wherein the substrate comprises glass.

14. The non-transitory computer-readable medium of claim 10, wherein the planarization material comprises one of TiN, TiW, TaN, TiWCu, Oxide or SiN.

15. The non-transitory computer-readable medium of claim 10, wherein the first metal layer comprises Cu, Au, Ag, Al, or similar material.

16. The non-transitory computer-readable medium of claim 10, wherein the second metal layer comprises Cu, Au, Ag, Al, or similar material.

17. The non-transitory computer-readable medium of claim 10, wherein the dielectric comprises SiN, AlO₃, or high k material.

18. The non-transitory computer-readable medium of claim 10, wherein the first metal layer, the planarization material, the dielectric, and the second metal layer comprise a capacitor.

19. A passive device, comprising:
a substrate;
a seed layer on the substrate;
a first metal layer on the seed layer;
a planarization material on the first metal layer;
a dielectric on the planarization material; and
a second metal layer on the dielectric.

20. The passive device of claim 19, wherein the substrate comprises glass.

21. The passive device of claim 19, wherein the planarization material comprises one of TiN, TiW, TaN, TiWCu, Oxide or SiN.

22. The passive device of claim 19, wherein the first metal layer comprises Cu, Au, Ag, Al, or similar material.

23. The passive device of claim 19, wherein the second metal layer comprises Cu, Au, Ag, Al, or similar material.

24. The passive device of claim 19, wherein the dielectric comprises SiN, AlO₃, or high k material.

25. The passive device of claim 19, wherein the planarization material comprises a plurality of layers.

26. The passive device of claim 19, wherein the passive device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

27. A passive device, comprising:
a substrate;
a seed layer on the substrate;
first means for conducting on the seed layer;
means for forming a barrier on the first means for conducting;
means for insulating on the means for forming the barrier; and
second means for conducting on the means for insulating.

28. The passive device of claim 19, wherein the substrate comprises glass.

29. The passive device of claim 19, wherein the means for forming the barrier comprises one of TiN, TiW, TaN, TiWCu, Oxide or SiN.

30. The passive device of claim 19, wherein the passive device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
